(19) United States
(12) Patent Application Publication
(10) Pub. No.: US 2026/0013096 A1
(43) Pub. Date: Jan. 8, 2026

(54) BIT LINE WITH NON-UNIFORM WIDTH IN A MEMORY ARRAY

(71) Applicant: Taiwan Semiconductor Manufacturing Company, Ltd., Hsin-Chu (TW)

(72) Inventors: Ping-Wei Wang, Hsin-Chu (TW); Jui-Lin Chen, Taipei City (TW)

(21) Appl. No.: 19/282,900

(22) Filed: Jul. 28, 2025

Related U.S. Application Data
(63) Continuation of application No. 18/433,641, filed on Feb. 6, 2024.
(60) Provisional application No. 63/587,088, filed on Sep. 30, 2023.

(51) Int. Cl. H10B 10/00

(52) U.S. Cl. CPC H10B 10/125; H10B 10/18

(57) ABSTRACT

A semiconductor device according to the present disclosure includes a memory array having a plurality of memory cells arranged in a row, and an interconnect structure disposed over the memory cells and having a bit line coupled to each of the memory cells arranged in the row. The bit line has a first segment coupled to a first portion of the memory cells and a second segment coupled to a second portion of the memory cells. The first segment has a first width and the second segment has a second width that is smaller than the first width.

### PRIORITY DATA

This is a continuation application of U.S. patent application Ser. No. 18/433,641, field Feb. 6, 2024, which claims benefit of U.S. Provisional Patent Application No. 63/587,088, filed Sep. 30, 2023, each of which is incorporated herein by reference in its entirety.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far, these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

Such scaling down in integrated circuit technology has not only complicated the manufacturing processes but also raised specific challenges in the design and functionality of memory arrays within memory devices. For example, operations of memory cells at different locations in a memory array raise a need for tailored structural designs for signal lines (e.g., bit lines) coupled to the memory cells. The traditional approach of employing bit lines with one uniform width across all the memory cells in the same row is increasingly inadequate, as it does not optimally address the varying performance demands of these memory cells. A uniform width for bit lines deployed in a memory array can lead to suboptimal performance, where the specific needs of memory cells at different locations in a memory array are not fully met. This discrepancy highlights the need for a differentiated approach in bit line architecture to enhance the overall efficiency and performance of memory devices, particularly in the context of advanced semiconductor technologies.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a block diagram of a semiconductor device having a memory macro, according to various aspects of the present disclosure.

FIG. 2 is a block diagram of a memory macro having a memory array, according to various aspects of the present disclosure.

FIG. 3 is a circuit schematic of a static random-access memory (SRAM) cell, according to various aspects of the present disclosure.

FIG. 4 illustrates a cross-sectional view of various layers of a memory device, according to various aspects of the present disclosure.

FIGS. 5 and 6 illustrate a layout including device layer and metal layer, respectively, of the SRAM cell as in FIG. 3, according to various aspects of the present disclosure.

FIGS. 7 and 8 illustrate a layout including device layer and metal layer, respectively, of a portion of the memory macro as in FIG. 2, according to various aspects of the present disclosure.

FIG. 9 illustrates a layout including metal layer of a portion of a memory circuit that includes bit lines having two different widths, according to various aspects of the present disclosure.

FIG. 10 illustrates fragmentary cross-sectional views along cross sections A-A, B-B, A′-A′, and B′-B′ in FIG. 9, according to various aspects of the present disclosure.

FIG. 11 illustrates a layout including metal layer of a portion of a memory circuit that includes bit lines having three different widths, according to various aspects of the present disclosure.

FIG. 12 illustrates a layout including metal layer of a portion of a memory circuit that includes bit lines extending from two opposing I/O regions, according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.5 nm to 5.5 nm where manufacturing tolerances associated with depositing the material layer are known to be +/−10% by one of ordinary skill in the art. When describing aspects of a transistor, source/drain region(s) may refer to a source or a drain, individually or collectively, dependent upon the context.

Static Random Access Memory (SRAM) is a semiconductor memory that retains data statically as long as it is powered. Unlike dynamic RAM (DRAM), SRAM is faster and more reliable, eliminating the need for constant refreshing. An SRAM macro includes memory cells and logic cells. The memory cells are also referred to as bit cells, and are configured to store memory bits. The memory cells may be arranged in rows and columns in forming an array. The logic cells may be standard cells (STD cells), such as inventor (INV), AND, OR, NAND, NOR, Flip-flip, SCAN and so on. The logic cells are disposed around the memory cells, and are configured to implement various logic functions. Multilayer interconnect structures provide metal tracks (metal lines) for interconnecting power lines and signal lines between the memory cells and logic cells. Memory cells at different locations may have different structural design needs to achieve optimal performance. For instance, a memory cell located close to logic cells may need a structural design for its bit line that minimizes resistance as other memory cells in the same row and thus coupled to the same bit line will also “see” the resistance in series. A bit line with a low resistance affords a larger voltage headroom. In contrast, a memory cell located far away from the logic cells may need a structural design for its bit line that minimizes latency with reduced parasitic capacitance as such a memory cell generally suffers from a reduced circuit speed. Thus, bit lines in an SRAM array with one uniform bit line width across different memory cells might result in suboptimal performance, as it does not meet the unique requirements of each memory cell.

The present disclosure introduces a bit line structure providing different bit line widths in an SRAM array. In one embodiment, an SRAM array may feature two or more bit line widths for memory cells at different distances from logic cells, enhancing circuit performance.

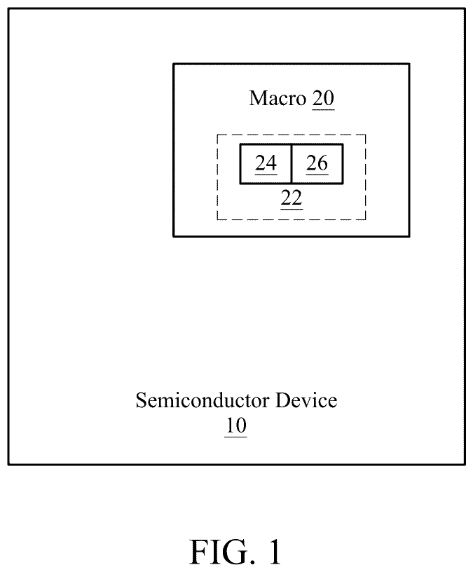

Reference now is made to FIG. 1. FIG. 1 is a simplified block diagram of a semiconductor device (or IC) 10, in accordance with some embodiments of the present disclosure. The semiconductor device 10 can be, e.g., a microprocessor, an application specific integrated circuit (ASIC), a field programmable gate array (FPGA), a digital signal processor (DSP), or a portion thereof, that includes various passive and active microelectronic devices such as resistors, capacitors, inductors, diodes, p-type field effect transistors (PFETs), n-type field effect transistors (NFETs), FinFET, gate-all-around (GAA) transistors (such as nanosheet FETs or nanowire FETs), other types of multi-gate FETs, metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, memory devices, other suitable components, or combinations thereof. The exact functionality of the semiconductor device 10 is not a limitation to the provided subject matter.

The semiconductor device 10 includes a memory macro (hereinafter, macro) 20. In some embodiments, the macro 20 is a static random-access memory (SRAM) macro, such as a single-port SRAM macro, a dual-port SRAM macro, or other types of SRAM macro. However, the present disclosure contemplates embodiments, where macro 20 is another type of memory, such as a dynamic random-access memory (DRAM), a non-volatile random access memory (NVRAM), a flash memory, or other suitable memory. FIG. 1 has been simplified for the sake of clarity to better understand the inventive concepts of the present disclosure. Additional features can be added in the macro 20, and some of the features described below can be replaced, modified, or eliminated in other embodiments of the macro 20.

In some embodiments, the macro 20 includes memory cells and peripheral circuits. The memory cells are also referred to as bit cells, and are configured to store memory bits. The peripheral cells are also referred to as logic cells that are disposed around the bit cells, and are configured to implement various logic functions. The logic functions of the logic cells include, for example, write and/or read decoding, word line selecting, bit line selecting, data driving and memory self-testing. The logic functions of the logic cells described above are given for the explanation purpose. Various logic functions of the logic cells are within the contemplated scope of the present disclosure. In the illustrated embodiment, the macro 20 includes a circuit region 22 in which at least a memory array 24 and at least a peripheral circuit 26 are positioned in close proximity to each other. The memory array 24 includes many memory cells arranged in rows and columns. The peripheral circuit 26 includes logic cells. Generally, the peripheral circuit 26 may include many logic cells to provide read operations and/or write operations to the memory cells in the memory array 24. The macro 20 may include more than one memory array 24 and more than one peripheral circuit 26. Transistors in the one or more memory arrays 24 and the one or more peripheral circuits 26 may be implemented with various PFETs and NFETs such as planar transistors or non-planar transistors including various FinFET transistors, GAA transistors, or a combination thereof. GAA transistors refer to transistors having gate electrodes surrounding transistor channels, such as vertically-stacked gate-all-around horizontal nanowire or nanosheet MOSFET devices. The following disclosure will continue with one or more GAA examples to illustrate various embodiments of the present disclosure. It is understood, however, that the application should not be limited to a particular type of device, except as specifically claimed. For example, aspects of the present disclosure may also apply to implementation based on FinFETs or planar FETs.

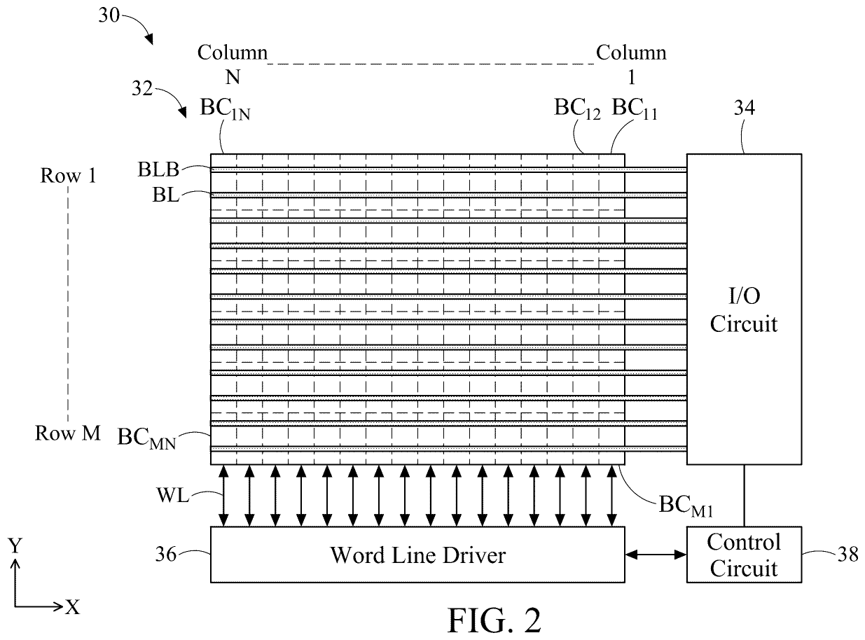

FIG. 2 shows a portion of a macro 30, which includes a memory array 32, an input/output (I/O) circuit 34, a word line driver 36, and a control circuit 38. In some embodiments, the macro 30 can be implemented as the circuit region 22 in FIG. 1; the memory array 32 can be implemented as the memory array 24 in FIG. 1; and the input/output (I/O) circuit 34, the word line driver 36, and the control circuit 38 collectively can be implemented as the peripheral circuit 26 in FIG. 1. FIG. 2 has been simplified for the sake of clarity to better understand the inventive concepts of the present disclosure. Additional features can be added in the macro 30, and some of the features described below can be replaced, modified, or eliminated in other embodiments of the macro 30.

The memory array 32 includes memory cells arranged in rows and columns. In the illustrated embodiment, the memory cells are arranged from Row 1 to Row M each extending along a first direction (here, in the X direction) and in Column 1 to Column N each extending along a second direction (here, in the Y direction), where M and N are positive integers. Generally, N is a power of 2, such as 64, 128, 256, 512, and so on. The present disclosure contemplates N being any other integer. For simplicity of illustration, only a few rows and a few columns and the corresponding memory cells are shown in FIG. 2. Each memory cell stores one bit of data. Accordingly, a memory cell is also referred to as a bit cell or denoted as BCₘₙ according to its location in the memory array 32, where m representing the row and n representing the column. For example, BC₁₁ represents the memory cell located in the first row (Row 1) and the first column (Column 1), which is the memory cell closest to the I/O circuit 34 in the first row (Row 1); BC₁₂ represents the memory cell located in the first row (Row 1) and the second column (Column 2), which is the memory cell second closest to the I/O circuit 34 in the first row (Row 1); BC_{1N} represents the memory cell located in the first row (Row 1) and the last column (Column N), which is the memory cell farthest away from the I/O circuit 34 in the first row (Row 1); and BC_{MN} represents the memory cell located in the last row (Row M) and the last column (Column N), which is the memory cell farthest away from the I/O circuit 34 in the last row (Row M). A memory cell BCₘₙ may be referred to as a BC for simplicity.

Rows 1 to M each include a bit line pair extending along the X direction, such as a bit line (BL) and a bit line bar (BLB) (also referred to as a complementary bit line), that facilitate reading data from and/or writing data to respective memory cells BC in true form and complementary form on a row-by-row basis. Columns 1 to M each includes a word line (WL) that facilitates access to respective memory cells BC on a column-by-column basis. Each memory cell BC is electrically connected to a respective BL, a respective BLB, and a respective WL.

The I/O circuit 34 is coupled to the memory array 32 through the bit line pairs BL and BLB. The I/O circuit 34 is configured to select one of the rows in the memory array 32, and to provide bit line signal on one of the bit line pairs that is arranged on the selected row, in some embodiments. The bit line signal is transmitted through the selected bit line pair BL and BLB to the corresponding memory cells BC, for writing the bit data into, or reading the bit data from, the corresponding memory cells BC.

The word line driver 36 is coupled to the memory array 32 through the word lines WL. The word line driver 36 is configured to select one of the columns in the memory array 32, and to provide word line signal on one of the word lines WL that is arranged on the selected column, in some embodiments. The word line signal is transmitted through the selected word line WL to the corresponding memory cells BC, for writing the bit data into, or reading the bit data from, the corresponding memory cells BC.

The control circuit 38 is coupled to and disposed next to both of the I/O circuit 34 and the word line driver 36. The control circuit 38 configures the I/O circuit 34 and the word line driver 36 to generate one or more signals to select at least one WL and at least one bit line pair (here, BL and BLB) to access at least one of memory cells BC for read operations and/or write operations. The control circuit 38 includes any circuitry suitable to facilitate read/write operations from/to memory cells BC, including but not limited to, a column decoder circuit, a row decoder circuit, a column selection circuit, a row selection circuit, a read/write circuit (for example, configured to read data from and/or write data to memory cells BC corresponding to a selected bit line pair (in other words, a selected column)), other suitable circuit, or combinations thereof. In some embodiments, the control circuit 38 is implemented by a processor. In some other embodiments, the control circuit 130 is integrated with a processor. The processor is implemented by a central processing unit (CPU), a multi-processor, a distributed processing system, an application specific integrated circuit (ASIC), and/or a suitable processing unit.

In a write or read operation, at least one bit line pair and at least one word line WL are respectively selected by the I/O circuit 34 and the word line driver 36. When one word line WL on one corresponding column is selected, the bit line signal is transmitted from the I/O circuit 34 to one corresponding memory cell BC, or the bit line signal is transmitted from the memory cell BC to the I/O circuit 34. A memory cell located far away from the I/O circuit 34, such as memory cell BC_{1N}, is more sensitive to latency impacted by parasitic capacitance. However, the transmitting path along the signal lines in the bit line pair (here, BL and BLB extending through Columns 1 to N) to such a memory cell is relatively long and easily introduces a large parasitic capacitance. Therefore, a memory cell located far away from the I/O circuit 34 may want to “see” a narrower signal line thus a reduced parasitic capacitance. In a comparison, for a memory cell located near the I/O circuit 34, such as memory cell BC₁₁, the transmission path along the signal lines in the bit line pair (here, BL and BLB extending through Columns 1 to N) is relatively short, and the memory cell is less sensitive to parasitic capacitance. Therefore, a memory cell located close to the I/O circuit 34 may want to “see” a wider signal line thus an enlarge voltage headroom. Accordingly, memory cells located at different columns of a memory array have different requirements on dimensions of the signal lines, such as widths of the BL and BLB in the bit line pair, for further performance optimization.

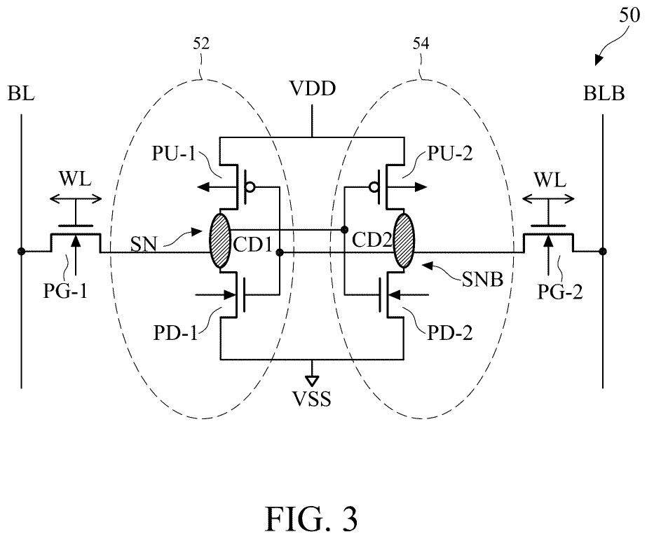

FIG. 3 is a circuit diagram of an exemplary SRAM cell 50, which can be implemented as a memory cell BC in FIG. 2 and further implemented in the semiconductor device 10 in FIG. 1. In the illustrated embodiment, the SRAM cell 50 is a single-port (SP) six-transistor (6T) SRAM cell. In various embodiments, the SRAM cell 50 may be other types of memory cells, such as dual-port memory cell or a memory cell having more than six transistors. FIG. 3 has been simplified for the sake of clarity to better understand the inventive concepts of the present disclosure. Additional features can be added in single-port SRAM cell 50, and some of the features described below can be replaced, modified, or eliminated in other embodiments of single-port SRAM cell 50.

The exemplary SRAM cell 50 is a single port SRAM cell that includes six transistors: a pass-gate transistor PG-1, a pass-gate transistor PG-2, a pull-up transistor PU-1, a pull-up transistor PU-2, a pull-down transistor PD-1, and a pull-down transistor PD-2. In operation, the pass-gate transistor PG-1 and the pass-gate transistor PG-2 provide access to a storage portion of the SRAM cell 50, which includes a cross-coupled pair of inverters, an inverter 52 and an inverter 54. The inverter 52 includes the pull-up transistor PU-1 and the pull-down transistor PD-1, and the inverter 54 includes the pull-up transistor PU-2 and the pull-down transistor PD-2. In some implementations, the pull-up transistors PU-1, PU-2 are configured as p-type FinFET transistors or p-type GAA transistors, and the pull-down transistors PD-1, PD-2 are configured as n-type FinFET transistors or n-type GAA transistors.

A gate of the pull-up transistor PU-1 interposes a source (electrically coupled with a power supply voltage (VDD)) and a first common drain (CD1), and a gate of pull-down transistor PD-1 interposes a source (electrically coupled with a power supply voltage (VSS), which may be an electric ground) and the first common drain. A gate of pull-up transistor PU-2 interposes a source (electrically coupled with the power supply voltage (VDD)) and a second common drain (CD2), and a gate of pull-down transistor PD-2 interposes a source (electrically coupled with the power supply voltage (VSS)) and the second common drain. In some implementations, the first common drain (CD1) is a storage node (SN) that stores data in true form, and the second common drain (CD2) is a storage node (SNB) that stores data in complementary form. The gate of the pull-up transistor PU-1 and the gate of the pull-down transistor PD-1 are coupled with the second common drain (CD2), and the gate of the pull-up transistor PU-2 and the gate of the pull-down transistor PD-2 are coupled with the first common drain (CD1). A gate of the pass-gate transistor PG-1 interposes a source (electrically coupled with a bit line BL) and a drain, which is electrically coupled with the first common drain (CD1). A gate of the pass-gate transistor PG-2 interposes a source (electrically coupled with a complementary bit line BLB) and a drain, which is electrically coupled with the second common drain (CD2). The gates of the pass-gate transistors PG-1, PG-2 are electrically coupled with a word line WL. In some implementations, the pass-gate transistors PG-1, PG-2 provide access to the storage nodes SN, SNB during read operations and/or write operations. For example, the pass-gate transistors PG-1, PG-2 couple the storage nodes SN, SNB respectively to the bit lines BL, BLB in response to a voltage applied to the gates of the pass-gate transistors PG-1, PG-2 by the word line WL.

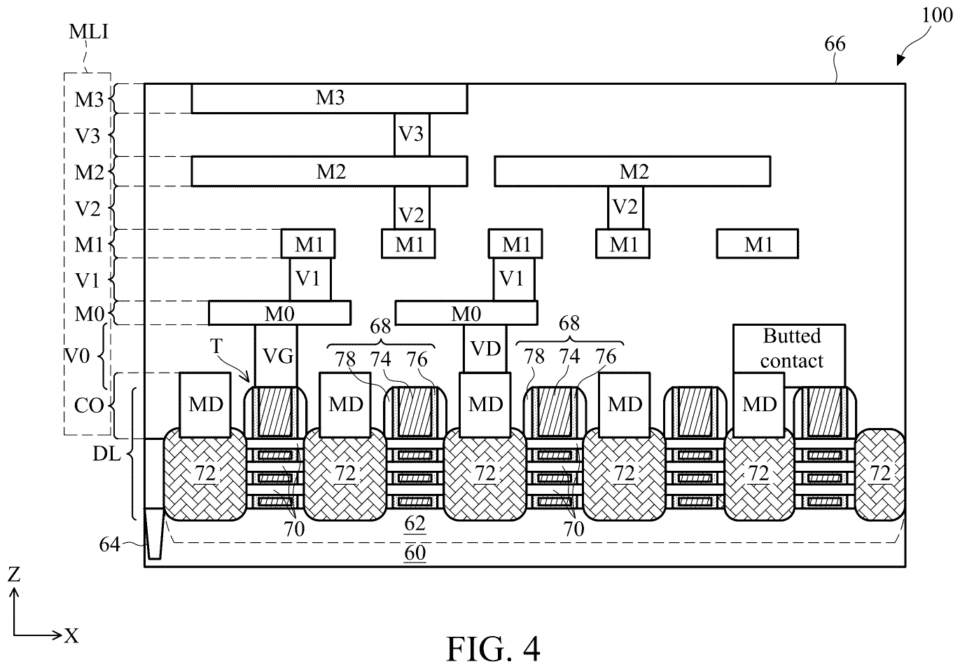

FIG. 4 is a fragmentary diagrammatic cross-sectional view of a semiconductor device 100 including various layers (levels) that can be fabricated over a semiconductor substrate (or wafer) 60 to form a portion of a memory, such as the memory macro 30 of FIG. 2, and/or a portion of an SRAM cell, such as the SRAM cell 50 of FIG. 3, according to various aspects of the present disclosure. In FIG. 4, the various layers include a device layer DL and a multilayer interconnect MLI disposed over the device layer DL. Device layer DL includes devices (e.g., transistors, resistors, capacitors, and/or inductors) and/or device components (e.g., doped wells, gate structures, and/or source/drain features). In some embodiments, device layer DL includes substrate 60, doped regions 62 disposed in substrate 60 (e.g., n-wells and/or p-wells), isolation features 64, and transistors T. In the depicted embodiment, transistors T include suspended channel layers 70 and gate structures 68 disposed between source/drains 72, where gate structures 68 wrap and/or surround suspended channel layers 70. Each gate structure 68 has a metal gate stack formed from a gate electrode 74 disposed over a gate dielectric 76 and gate spacers 78 disposed along sidewalls of the metal gate stack. Multilayer interconnect MLI electrically couples various devices and/or components of device layer DL, such that the various devices and/or components can operate as specified by design requirements for the memory.

In the depicted embodiment, multilayer interconnect MLI includes a contact layer (CO level), a via zero layer (V0 level), a metal zero (M0) level, a via one layer (V1 level), a metal one layer (M1 level), a via two layer (V2 level), a metal two layer (M2 level), a via three layer (V3 level), and a metal three layer (M3 level). The present disclosure contemplates multilayer interconnect MLI having more or less layers and/or levels, for example, a total number of 2 to 10 metal layers (levels) of the multilayer interconnect MLI. Each level of multilayer interconnect MLI includes conductive features (e.g., metal lines, metal vias, and/or metal contacts) disposed in one or more dielectric layers (e.g., an interlayer dielectric (ILD) layer and a contact etch stop layer (CESL)). In some embodiments, conductive features at a same level of multilayer interconnect MLI, such as M0 level, are formed simultaneously. In some embodiments, conductive features at a same level of multilayer interconnect MLI have top surfaces that are substantially planar with one another and/or bottom surfaces that are substantially planar with one another. CO level includes source/drain contacts (MD) disposed in a dielectric layer 66; V0 level includes gate vias VG, source/drain contact vias VD, and butted contacts disposed in the dielectric layer 66; M0 level includes M0 metal lines disposed in dielectric layer 66, where gate vias VG connect gate structures to M0 metal lines, source/drain vias V0 connect source/drains to M0 metal lines, and butted contacts connect gate structures and source/drains together and to M0 metal lines; V1 level includes V1 vias disposed in the dielectric layer 66, where V1 vias connect M0 metal lines to M1 metal lines; M1 level includes M1 metal lines disposed in the dielectric layer 66; V2 level includes V2 vias disposed in the dielectric layer 66, where V2 vias connect M1 lines to M2 lines; M2 level includes M2 metal lines disposed in the dielectric layer 66; V3 level includes V3 vias disposed in the dielectric layer 66, where V3 vias connect M2 lines to M3 lines.

An exemplary manufacturing flow of forming the device layer DL and the multilayer interconnect MLI of the semiconductor device 100, according to various aspects of the present disclosure, may include forming active regions on a substrate, forming isolation structures (e.g., shallow-trench isolation (STI)) between adjacent active regions, forming dummy gates over the active regions and gate spacers on sidewalls of the dummy gates, recessing the active regions to form source/drain recesses, forming inner spacers and source/drain features in the source/drain recesses, depositing interlayer dielectric (ILD) layer over the source/drain features and the dummy gate structure, performing a planarization process (e.g., a chemical mechanical planarization (CMP) process) to expose the dummy gate structures, replacing the dummy gate structures with metal gate structures, and forming contacts, vias, and metal layers in the multilayer interconnect MLI.

FIG. 4 has been simplified for the sake of clarity to better understand the inventive concepts of the present disclosure. Additional features can be added in the various layers of the memory, and some of the features described can be replaced, modified, or eliminated in other embodiments of the memory. FIG. 4 is merely an example and may not reflect an actual cross-sectional view of the memory macro 30 and/or the SRAM cells 50 that is discussed in further detail below.

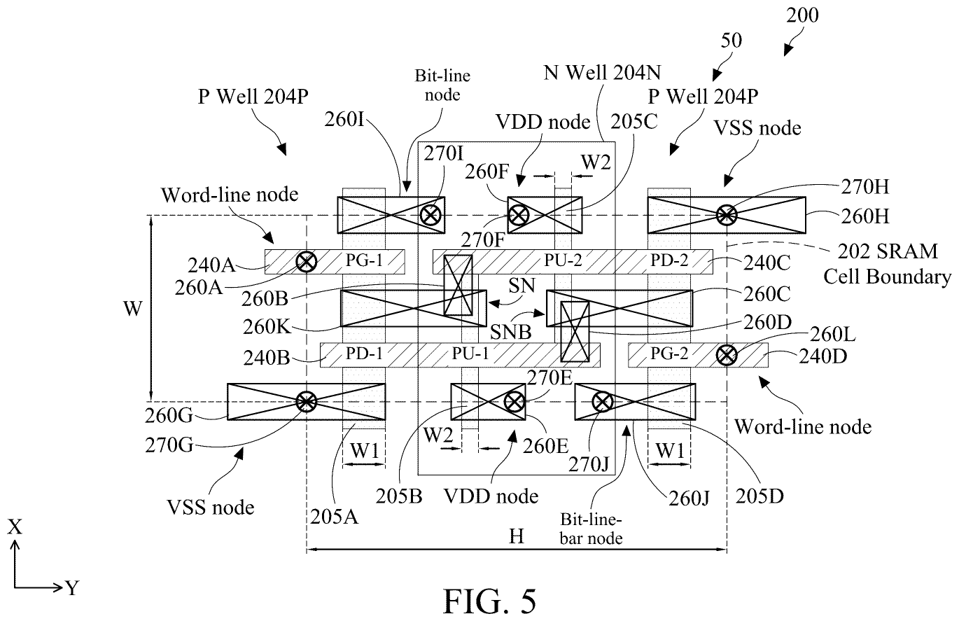

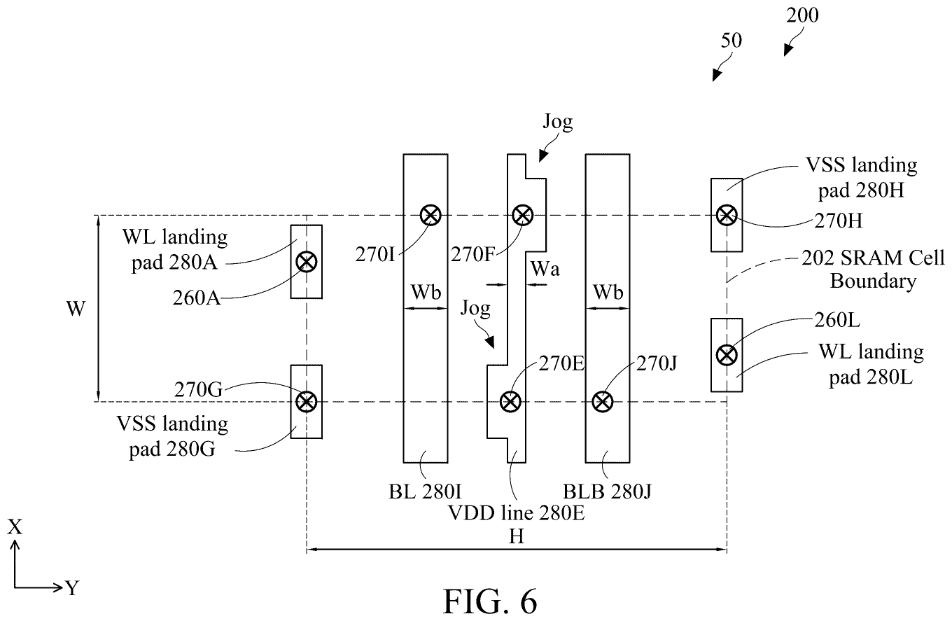

FIGS. 5 and 6 illustrate an exemplary layout 200 of the SRAM cell 50 as in FIG. 3, in which FIG. 5 illustrates the DL level, CO level, and V0 level of the layout 200 and FIG. 6 illustrates V0 level and M0 level of the layout 200. The SRAM cell 50 has a cell boundary 202 represented by dotted lines in FIGS. 5 and 6. The cell boundary 202 is a rectangular box that is longer in the Y-direction than in the X-direction, for example, about 3.5 times to about 6 times longer. The first dimension of the cell boundary 202 along the X-direction is denoted as a cell width W, and the second dimension of the cell boundary 202 along the Y-direction is denoted as a cell height H. Where the SRAM cell 50 is repeated in a memory array, the cell width W may represent and be referred to as a memory cell pitch in the memory array along the X-direction, and the cell height H may represent and be referred to as a memory cell pitch in the memory array along the Y-direction. In the illustrated embodiment, the cell width W is two times a poly pitch. A poly pitch refers to a minimum center-to-center distance between two adjacent gate structures along the X-direction.

The SRAM cell 50 includes active regions 205 (including 205A, 205B, 205C, and 205D) that are oriented lengthwise along the X-direction, and gate structures 240 (including 240A, 240B, 240C and 240D) that are oriented lengthwise along the Y-direction perpendicular to the X-direction. The active regions 205B and 205C are disposed over an n-type well (or n-well) 204N. The active regions 205A and 205D are disposed over p-type wells (or p-wells) 204P that are on both sides of the n-well 204N along the Y-direction. The gate structures 240 engage the channel regions of the respective active regions 205 to form transistors. In that regard, the gate structure 240A engages the channel region of the active region 205A to form an n-type transistor as the pass-gate transistor PG-1; the gate structure 240B engages the channel region of the active region 205A to form an n-type transistor as the pull-down transistor PD-1 and engages the channel region of the active region 205B to form a p-type transistor as the pull-up transistor PU-1; the gate structure 240C engages the channel region of the active region 205D to form an n-type transistor as the pull-down transistor PD-2 and engages the channel region of the active region 205C to form a p-type transistor as the pull-up transistor PU-2; and the gate structure 240D engages the channel region of the active region 205D to form an n-type transistor as the pass-gate transistor PG-2. In the present embodiment, each of the channel regions is in the form of vertically-stacked nanostructures and each of the transistors PU-1, PU-2, PD-1, PD-2, PG-1, and PG-2 is a GAA transistor. Alternatively, each of the channel regions 215A-F is in the form of a fin and each of the transistors PU-1, PU-2, PD-1, PD-2, PG-1, and PG-2 is a FinFET transistor.

Different active regions in different transistors of the SRAM cell 50 may have different widths (e.g., dimensions measured in the Y-direction) in order to optimize device performance. In more detail, the active region 205A of the pull-down transistor PD-1 and the pass-gate transistor PG-1 has a width W1, the active region 205B of the pull-up transistor PU-1 has a width W2, the active region 205C of the pull-up transistor PU-2 has a width W2, and the active region 205D of the pass-gate PG-2 and the pull-down transistor PD-2 has a width W1. The widths W1 and W2 may also be measured in portions of the active regions corresponding to the channel regions. In other words, these portions of the active regions (from which the widths W1 and W2 are measured) are the channel regions (e.g., the vertically-stacked nanostructures of GAA devices) of the transistors. To optimize SRAM performance, in some embodiments, the width W1 is configured to be greater than the width W2 (W1>W2), as an effort to balance the speed among the n-type transistors and the p-type transistors. In some embodiments, a ratio of W1/W2 may range from about 1.1 to about 3.

The width W1 being larger than the width W2 increases strength of the n-type transistors in the SRAM cell 50, which leads to higher current handling capability of the SRAM cell 50. Such configuration of active regions is suitable for high-current applications (such SRAM cell is referred to as high-current SRAM cell). In some other embodiments, the widths W1 and W2 may be the same (W1=W2). The reduced width W1 allows the SRAM cell 50 to have a smaller cell height H. Such configuration of active regions is suitable for high-density applications (such SRAM cell is referred to as high-density SRAM cell). Taking the macro 20 in FIG. 1 as an example, in one embodiment, the memory macro 20 may include memory arrays 24 all made of high-current SRAM cells; in another embodiment, the memory macro 20 may include memory arrays 24 all made of high-density SRAM cells; and yet in another embodiment, the memory macro 20 may include some memory arrays 24 made of high-current SRAM cells and some other memory arrays 24 made of high-density SRAM cells.

The SRAM cell 50 further includes conductive features in the CO level, V0 level, M0 level, and even higher metal levels (e.g., M1 level, M2 level, etc.). A gate contact 260A electrically connects a gate of the pass-gate transistor PG-1 (formed by gate structure 240A) to a first word line WL landing pad 280A. The first WL landing pad 280A is electrically coupled to a word line WL located at a higher metal level. A gate contact 260L electrically connects a gate of the pass-gate transistor PG-2 (formed by gate structure 240D) to a second word line WL landing pad 280L. The second WL landing pad 280L is electrically coupled to a word line WL located at a higher metal level. A source/drain (S/D) contact 260K electrically connects a drain region of the pull-down transistor PD-1 (formed on the active region 205A (which may include n-type epitaxial source/drain features)) and a drain region of the pull-up transistor PU-1 (formed on the active region 205B (which may include p-type epitaxial source/drain features)), such that a common drain of pull-down transistor PD-1 and pull-up transistor PU-1 form a storage node SN. A gate contact 260B electrically connects a gate of the pull-up transistor PU-2 (formed by gate structure 240C) and a gate of the pull-down transistor PD-2 (also formed by gate structure 240C) to the storage node SN. The gate contact 260B may be a butted contact abutting the S/D contact 260K. An S/D contact 260C electrically connects a drain region of the pull-down transistor PD-2 (formed on the active region 205D (which may include n-type epitaxial source/drain features)) and a drain region of the pull-up transistor PU-2 (formed on the active region 205C (which may include p-type epitaxial source/drain features)), such that a common drain of pull-down transistor PD-2 and pull-up transistor PU-2 form a complementary storage node SNB. A gate contact 260D electrically connects a gate of the pull-up transistor PU-1 (formed by the gate structure 222) and a gate of the pull-down transistor PD-1 (also formed by the gate structure 240B) to the complementary storage node SNB. The gate contact 260D may be a butted contact abutting the S/D contact 260C.

An S/D contact 260E and an S/D contact via 270E landing thereon electrically connect a source region of pull-up transistor PU-1 (formed on the active region 205B (which can include p-type epitaxial source/drain features)) to a VDD line 280E. The VDD line 280E is electrically coupled to a power supply voltage VDD. An S/D contact 260F and an S/D contact via 270F landing thereon electrically connect a source region of the pull-up transistor PU-2 (formed on the active region 205C (which may include p-type epitaxial source/drain features)) to the VDD line 280E. An S/D contact 260G and an S/D contact via 270G landing thereon electrically connect a source region of the pull-down transistor PD-1 (formed on the active region 205A (which may include n-type epitaxial source/drain features)) to a first VSS landing pad 280G. The first VSS landing pad 280G is electrically coupled to an electric ground VSS. An S/D contact 260H and an S/D contact via 270H landing thereon electrically connect a source region of the pull-down transistor PD-2 (formed on the active region 205D (which may include n-type epitaxial source/drain features)) to a second VSS landing pad 280H. The second VSS landing pad 280H is electrically coupled to an electric ground VSS. The S/D contact 260G and the S/D contact 260H may be device-level contacts that are shared by adjacent SRAM cells 50 (e.g., four SRAM cells 50 abutting at a same corner may share one S/D contact 260H). An S/D contact 260I and an S/D contact via 270I landing thereon electrically connect a source region of the pass-gate transistor PG-1 (formed on the active region 205A (which may include n-type epitaxial source/drain features)) to a bit line BL 280I. An S/D contact 260J and an S/D contact via 270J landing thereon electrically connect a source region of the pass-gate transistor PG-2 (formed on the active region 205D (which may include n-type epitaxial source/drain features)) to a complementary bit line (bit line bar) BLB 280J.

Conductive features in the CO level, M0 level, and higher metal levels (e.g., M1 level, M2 layer, etc) are routed along a first routing direction or a second routing direction that is different than the first routing direction. For example, the first routing direction is the X-direction (and substantially parallel with the lengthwise direction of active regions 205A-205D) and the second routing direction is the Y-direction (and substantially parallel with the lengthwise direction of gate structures 240A-240D). In the depicted embodiment, source/drain contacts (260C, 260E, 260F, 260G, 260H, 260I, 260J) have longitudinal (lengthwise) directions substantially along the Y-direction (i.e., second routing direction), and butted contacts (260B, 260D) have longitudinal directions substantially along the X-direction (i.e., first routing direction). Metal lines of even-numbered metal layers (i.e., M0 level and M2 level) are routed along the X-direction (i.e., the first routing direction) and metal lines of odd-numbered metal layers (i.e., M1 level and M3 level) are routed along the Y-direction (i.e., the second routing direction). For example, in the M0 level as shown in FIG. 6, the bit line 280I, bit line bar 280J, VDD line 280E, VSS landing pad 280G, VSS landing pad 280H, word line landing pad 280A, word line landing pad 280L have longitudinal directions substantially along the X-direction. Further, since the metal lines in the same metal level (e.g., the M0 level) have the same longitudinal directions, the metal lines can be positioned in metal tracks arranged in parallel. A metal track may include one or more metal lines. For example, a metal track may include a single metal line that extends through the entire SRAM cell, or a metal track may include one or more local metal lines that do not extend through the entire SRAM cell.

The illustrated metal lines are generally rectangular-shaped (i.e., each has a length greater than its width), but the present disclosure contemplates metal lines having different shapes and/or combinations of shapes to optimize and/or improve performance (e.g., reduce resistance) and/or layout footprint (e.g., reduce density). For example, the VDD line 280E may optionally have jogs added as shown in FIG. 6. The jog portion of the VDD line 280E has a larger width than other portion of the VDD line 280E. The jog may add about 1% to about 50% extra width to the VDD line 280E. The jogs are added to interconnection regions (areas) of the VDD line 280E to increase cross-sectional areas of the interconnection regions. Increasing cross-sectional areas of the interconnection regions of the VDD line 280E allows for increasing cross-sectional areas of the S/D contact vias 270E and 270F in the V0 level, which reduces routing resistance between the connection of the VDD line 280E and respective source/drain contacts (and thus to underlying source/drain regions).

“Landing pad” generally refers to metal lines in metal layers that provide intermediate, local interconnection for the SRAM cell, such as (1) an intermediate, local interconnection between a device-level feature (e.g., gate or source/drain) and a bit line, a bit line bar, a word line, a voltage line or (2) an intermediate, local interconnection between bit lines, word lines, or voltage lines. For example, the VSS landing pad 280G is connected to source/drain contact 260G of the transistor PD-1 and further connected to a VSS line located in a higher metal level, the VSS landing pad 280H is connected to source/drain contact 260H of the transistor PD-2 and further connected to a VSS line located in a higher metal level, the WL landing pad 280A is connected to a gate of the transistor PG-1 and further connected to a word line WL located in a higher metal level, and the WL landing pad 280L is connected to a gate of the transistor PG-2 and further connected to a word line WL located in a higher metal level. Landing pads have longitudinal dimensions that are large enough to provide a sufficient landing area for their overlying vias (and thus minimize overlay issues and provide greater patterning flexibility). In the depicted embodiment, landing pads have longitudinal dimensions that are less than dimensions of the SRAM cell 50, such as dimensions along the X-direction that are less than cell width W and dimensions along the Y-direction that are less than cell height H. As a comparison to the landing pads, the bit line 280I, the bit line bar 280J, and the VDD line 280E have longitudinal dimensions along the X-direction that are greater than cell width W of the SRAM cell 50. As they travel through the entire SRAM cell 50 along the X-direction, the bit line 280I, the bit line bar 280J, and the VDD line 280E at the M0 level are also referred to as global metal lines, while others are referred to as local metal lines (including landing pads). In some embodiments, a length of each of the bit line 280I, the bit line bar 280J, and the VDD line 280E is sufficient to allow electrical connection of multiple SRAM cells in a column (or a row) to the respective global metal line.

The metal lines (global metal lines and local metal lines) in the SRAM cell 50 at the M0 level may have different widths. For example, the VDD line 280E has a width Wa, and the bit line 280I and bit line bar 280J each have a width Wb. In some embodiments, the width Wb is larger than the width Wa (Wb>Wa). Having the largest width reserved to the bit line 280I and bit line bar 280J allows the signal lines in the bit line pair to generally benefit from a reduced resistance and thus a reduced voltage drop along the signal lines. In some embodiments, a ratio of width Wb to width Wa (i.e., Wb/Wa) is about 1.1 to about 2. In some embodiments, the width Wa is larger than the width Wb (Wa>Wb). Having the largest width reserved to the VDD line 280E allows the VDD line 280E to generally benefit from a reduced resistance and thus a reduced voltage drop along the power supply lines. In some embodiments, a ratio of width Wa to width Wb (i.e., Wa/Wb) is about 1.1 to about 2.

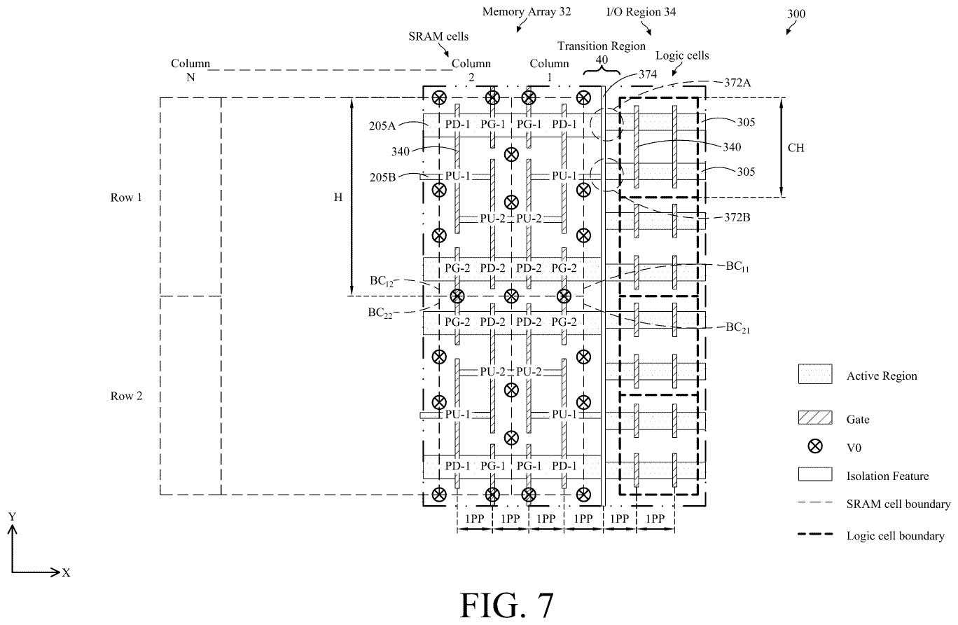

FIG. 7 illustrates the DL level and V0 level of a layout 300 of a portion of the memory macro 30 (FIG. 2), which includes first two rows (Rows 1-2) of the memory array 32 and a portion of the logic cells in the I/O circuit (or referred to as I/O region) 34. FIG. 7 has been simplified for the sake of clarity to better understand the inventive concepts of the present disclosure. For example, active regions, gate structures, gate-cut isolation features, and vias at the V0 level in the SRAM cells of the first two columns and first two rows (i.e., BC₁₁, BC₁₂, BC₂₁, BC₂₂) of the memory array 32 (FIG. 2) are shown, while numerous other features are omitted in FIG. 7.

The SRAM cells in the memory array 32 include a first type of active regions (e.g., 205A and 205B), and the logic cells in the I/O region 34 includes a second type of active regions (e.g., 305). The active regions in the memory array 32 are arranged along the Y-direction and oriented lengthwise in the X-direction. As discussed above, the active regions (e.g., 205A and 205B) may have different widths and/or the same width (e.g., W1 and W2 in FIG. 5). State differently, the memory array 32 may include high-current SRAM cells or high-density SRAM cells depending on application needs. Further, the memory macro 30 may include a first memory array 32 made of high-current SRAM cells and a second memory array 32 made of high-density SRAM cells. Each of the memory arrays 32 either made of high-current or high-density SRAM cells may adopt the bit line structure with the non-uniform width as to be explained in further detail below.

The active regions in the I/O region 34 are arranged along the Y-direction and oriented lengthwise in the X-direction. In the illustrated embodiment, the active regions 305 are evenly distributed along the Y-direction and each have a uniform width. The memory macro further includes gate structures 340 arranged along the X-direction and extending lengthwise in the Y-direction. In the illustrated embodiment, the gate structures 340 are evenly distributed along the X-direction with a uniform distance between two adjacent gate structures 340. The uniform distance is denoted as a gate pitch or a poly pitch (“PP”). The SRAM cell width W can also be measured by the number of poly pitches. In the illustrated embodiment, the SRAM cell width W is two times a poly pitch. The memory array 32's width along the X direction can also be measured by the number of poly pitches. Since each SRAM cell has a width W of two times a poly pitch, for having a number of N SRAM cells in a row, the memory array 32 has a width of 2*N poly pitches.

The gate structures 340 intersect the active regions in forming transistors. Transistors formed at the intersections of the active regions and the gate structures 340 within the memory array 32 are devoted to form SRAM cells. The transistors formed at the intersections of the active regions and the gate structures 340 within the I/O region 34 are devoted to form logic cells. In the illustrated embodiment, the transistors in the SRAM array 32 form a plurality of SRAM cells, such as SRAM cells BC₁₁, BC₁₂, BC₂₁, BC₂₂ (collectively, SRAM cells BC). Each SRAM cell BC in the array may use the layout 200 of the SRAM cell 50 as depicted in FIG. 5. In some embodiments, two adjacent SRAM cells in the X-direction are line symmetric with respect to a common boundary therebetween, and two adjacent SRAM cells in the Y-direction are line symmetric with respect to a common boundary therebetween. That is, the SRAM cell BC₁₂ is a duplicate cell for the SRAM cell BC₁₁ but flipped over the Y-axis; the SRAM cell BC₂₂ is a duplicate cell for the SRAM cell BC₁₂ but flipped over the X-axis; and the SRAM cell BC₂₁ is a duplicate cell for the SRAM cell BC₁₁ but flipped over the X-axis.

Some active regions extend through multiple SRAM cells in a row. For example, the active region for the transistors PD-1, PG-1 in the SRAM cell BC₁₁ extends through the SRAM cell BC₁₂ as the active region for its transistors PG-1, PD-1 and further through the other SRAM cells BC in the Row 1; the active region for the transistors PG-2, PD-2 in the SRAM cell BC₁₁ extends through the SRAM cell BC₁₂ as the active region for its transistors PD-2, PG-2 and further through the other SRAM cells BC in the Row 1; and the active region for the transistors PU-2 in the SRAM cell BCH extends into the SRAM cell BC₁₂ as the active region for its transistors PU-2. The active regions in the SRAM cells BC₂₁, BC₂₂ are similarly arranged. The vias at the V0 level in the SRAM cells are also illustrated in FIG. 7.

In the illustrated embodiment, the transistors in the I/O region 34 form a plurality of logic cells. The logic cells may be standard cells, such as inventor (INV), AND, OR, NAND, NOR, Flip-flip, SCAN and so on. The logic cells implement various logic functions to the SRAM cells BC. The logic functions of the logic cells include, for example, write and/or read decoding, word line selecting, bit line selecting, data driving and memory self-testing. As depicted, each logic cell has a logic cell height CH, which is half of the SRAM cell height H. Therefore, two logic cells have a boundary with opposing edges aligned with opposing edges of the boundary of one SRAM cell with the edges spaced in the Y-direction and each edge extending in the X-direction.

Between the opposing boundary lines of the SRAM cells in the memory array 32 and the logic cells in the I/O region 34 is an active region transition region 40, or simply as the transition region. Inside the transition region 40, the active regions 205A extending from the edge column of the SRAM cells meet the active regions 305 extending from the edge column of the logic cells. Since a pair of the active regions 205A, 305 that meet may have different widths, a jog is created at where the active regions 205A, 305 meet. A jog refers to a junction where two segments of different widths meet each other. For example, in the region 372A represented by a dotted circle, a relatively wide active region 205A meets a relatively narrow active region 305, creating a jog. The upper edges of the active regions 205A, 305 align, while the lower edges of the active regions 205A, 305 creates a step profile. Similarly, in the region 372B represented by another dotted circle, a relatively narrow active region 205B meets a relatively wide active region 305, creating another job. The lower edges of the active regions 205B, 305 align, while the upper edges of the active regions 205B, 305 creates a step profile.

As depicted in the layout 300, the transition region 40 has a span of one poly pitch between the opposing boundary lines of the SRAM cells and the logic cells along the X-direction. In the transition region 40, a dielectric feature (or isolation feature) 374 is oriented lengthwise in the Y-direction and provides isolation between the active regions in the memory array 32 and the I/O region 34. The dielectric feature 374 overlaps with the jogs. In the exemplary layout 300, the dielectric feature 374 continuously extends along the boundary lines of the SRAM cells and the logic cells in the Y-direction. In other words, the dielectric feature 374 is taller than the SRAM cell height H.

The dielectric feature 374 may be formed in a continuous-poly-on-diffusion-edge (CPODE) process. In a CPODE process, a polysilicon gate is replaced by a dielectric feature. For purposes of this disclosure, a “diffusion edge” may be equivalently referred to as an active edge, where for example an active edge abuts adjacent active regions. Before the CPODE process, the active edge may include a dummy GAA structure having a dummy gate structure (e.g., a polysilicon gate) and a plurality of vertically stacked nanostructures as channel layers. In addition, inner spacers may be disposed between adjacent nanostructures at lateral ends of the nanostructures. In various examples, source/drain epitaxial features are disposed on either side of the dummy GAA structure, such that the adjacent source/drain epitaxial features are in contact with the inner spacers and nanostructures of the dummy GAA structure. The subsequent CPODE etching process removes the dummy gate structure and the channel layers from the dummy GAA structure to form a CPODE trench. The dielectric material filling a CPODE trench for isolation is referred to as a CPODE feature. In some embodiments, after the CPODE features are formed, the remaining dummy gate structures are replaced by metal gate structures in a replacement gate (gate-last) process. State differently, in some embodiments, the CPODE feature replaces a portion or full of the otherwise continuous gate structure and is confined between the opposing gate spacers of the replaced portion of the gate structure. The dielectric feature 374 is also referred to as a gate-cut feature or a CPODE feature. Since the CPODE feature 374 is formed by replacing the previously-formed polysilicon gate structures, the CPODE feature 374 inherits the arrangement of the gate structures 340. That is, the CPODE feature 374 may have the same width as the gate structures 340 and the same pitch as the gate structures 340.

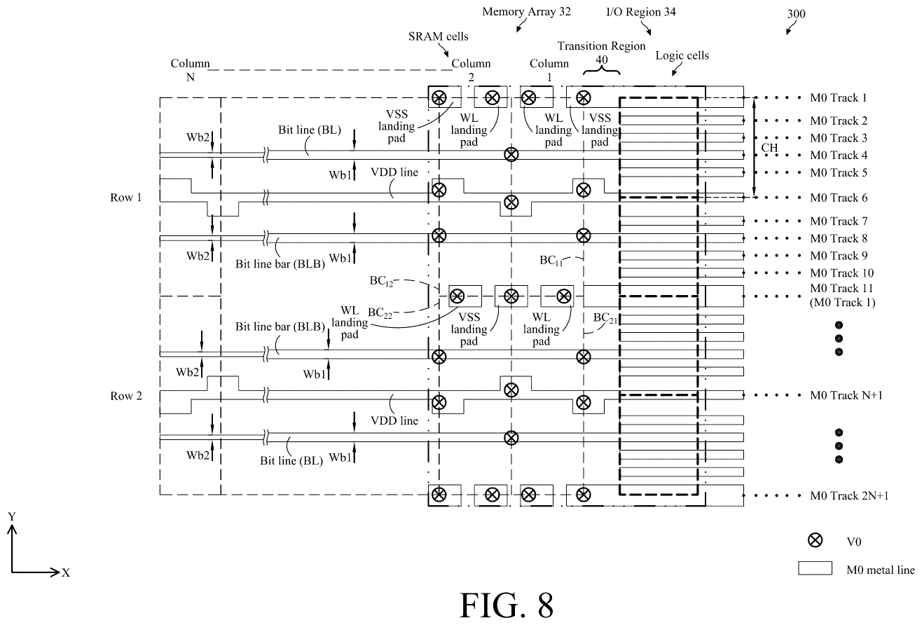

FIG. 8 illustrates the V0 level and M0 level of the layout 300 of the portion of the memory macro 30 (FIG. 2), which includes first two rows (Rows 1-2) of the memory array 32 and a portion of the logic cells in the I/O circuit 34. At the M0 level, the I/O region 34 includes a plurality of metal tracks arranged in parallel. Particularly, in the illustrated embodiment of the layout 300, two abutting logic cells include eleven metal tracks arranged in order from first (M0 Track 1) to eleventh (M0 Track 11) along the Y-direction. The center lines of the metal tracks are represented by the dashed lines in FIG. 8.

The metal lines in the SRAM cells are aligned with the metal tracks in the I/O region 34, allowing the metal lines in the logic cells to extend into the SRAM cells. Thus, there is no need for edge cells between the SRAM cells and the logic cells to provide metal transitions. In the M0 Track 1, a VSS line extends into the SRAM cell BC₁₁ and merges with the VSS landing pad. In the M0 Track 2, the metal line as a signal line in the logic cell remains in the boundary of the respective logic cell. In the M0 Track 3, the metal line as a signal line in the logic cell remains in the boundary of the respective logic cell. In the M0 Track 4, the metal line as the bit line BL in the logic cell also extends into and through the SRAM cells as a bit line BL for multiple SRAM cells in the same row. In the M0 Track 5, the metal line as a signal line in the logic cell remains in the boundary of the respective logic cell. In the M0 Track 6, the metal line as a VDD line in the logic cell also extends into and through the SRAM cells as a VDD line for multiple SRAM cells in the same row. In the M0 Track 7, the metal line as a signal line in the logic cell remains in the boundary of the respective logic cell. In the M0 Track 8, the metal line as the bit line bar BLB in the logic cell also extends into and through the SRAM cells as a bit line bar BLB for multiple SRAM cells in the same row. In the M0 Track 9, the metal line as a signal line in the logic cell remains in the boundary of the respective logic cell. In the M0 Track 10, the metal line as a signal line in the logic cell remains in the boundary of the respective logic cell. In the M0 Track 11, the metal line as a VSS line in the logic cell may extend through the boundary of the respective logic cell but does not contact the word line WL landing pad.

The boundary of an SRAM cell may abut the boundary of one or two logic cells. The one or two logic cells provide 2*N+1 metal tracks, where N is an integer. The metal line in the center metal track (the (N+1)^{th} metal track) extends into the SRAM cell as a common VDD line for both the SRAM cell and the one or two logic cells. The two metal lines in the two metal tracks in equal spacing from the center metal track extend into the SRAM cell as a bit line BL and a bit line bar BLB, respectively, for both the SRAM cell and the one or two logic cells. The two metal lines in the first and the (2*N+1)^{th} metal tracks extend through the boundary of the one or two logic cells and connect to one of the VSS landing pads in the SRAM cell.

In the illustrated embodiment, the metal lines in the metal tracks 4 and 8 extend from the logic cells and through the SRAM cells in the same row as a bit line BL and a bit line bar BLB, respectively. Alternatively, depending on the layout, it may be the metal lines in the metal tracks 2 and 10, or the metal tracks 3 and 9, or the metal tracks 5 and 7 that extend from the logic cells and through the SRAM cells as a bit line BL and a bit line bar BLB, respectively. In the context, the bit line BL and the complementary bit line BLB may also be collectively referred to as bit lines if not separately indicated.

In semiconductor memory design, one uniform bit line width is generally deployed across SRAM cells in the memory array. However, preferences for bit line width may vary depending on whether the SRAM cells are located close to the logic cells in the I/O region 34 or at a distance from the logic cells in the I/O region 34. For SRAM cells in the columns far away from the I/O region 34, narrower bit lines help achieving reduced parasitic capacitance, thereby enabling faster access times and lower power consumption. In contrast, for SRAM cells in the columns close to the I/O region 34, wider bit lines help achieving reduced resistance, which facilitates maintaining voltage headroom and signal integrity along the bit lines. In the illustrated embodiment, each of the bit lines (BL or BLB) has a non-uniform width (multiple widths), such as a larger width Wb1 for the SRAM cells in the columns closer to the I/O region 34 and a smaller width Wb2 (Wb2<Wb1) for the SRAM cells in the columns at a distance from the I/O region 34. The non-uniform width balances the performance needs for SRAM cells in different locations of the memory array. Details of the non-uniform width of the bit lines are further explained below.

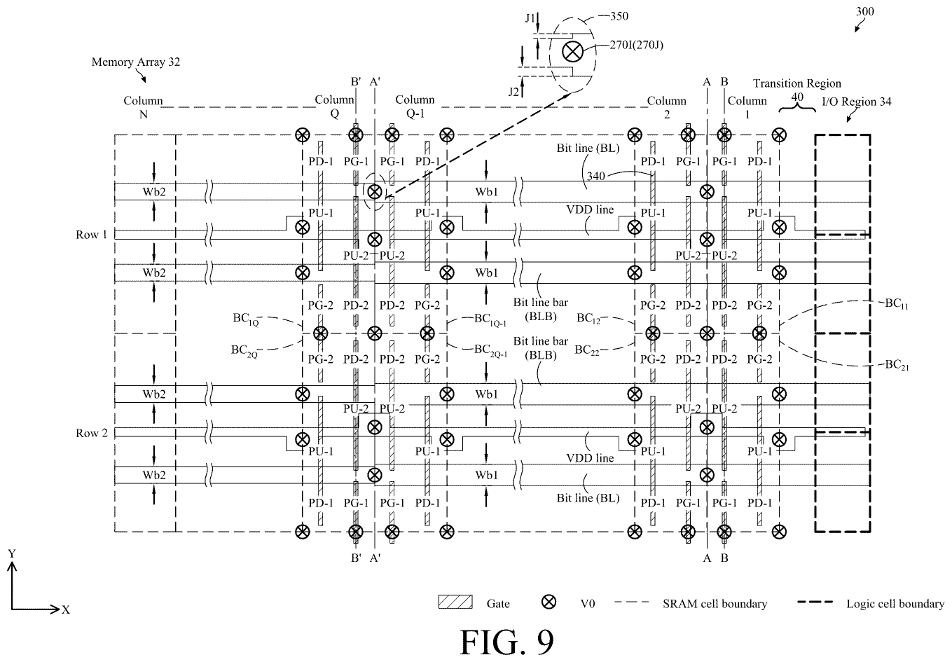

FIG. 9 is similar to FIG. 8 with further illustration of Columns Q−1 and Q where the transition of the bit line width from Wb1 to Wb2 occurs. Similar to FIG. 8, FIG. 9 also illustrates the V0 level and M0 level of the layout 300 of the portion of the memory macro 30 (FIG. 2). For simplicity, only the first two rows (Rows 1-2) of the memory array 32 are illustrated in FIG. 9.

In the memory array 32, each of the bit lines (cither BL or BLB) is shared by the memory cells in the same row starting from Column 1 to Column N. State differently, a number of N memory cells in the same row are coupled to (or fed by) the same bit line (either BL or BLB). In some embodiments, N is a power of 2, such as 64, 128, 256, 512, and so on. In furtherance of some embodiments, N is larger than 128 (e.g., N≥256). The present disclosure contemplates N being any other integer. Each of the bit lines is a straight line along the X direction but with a first portion (or segment) coupled to the SRAM cells from Column 1 to Column Q−1 and a second portion (or segment) coupled to the SRAM cells from Column Q to Column N. The first portion of the straight line has a larger width Wb1, and the second portion of the straight line as a smaller width Wb2 (Wb2<Wb1). That is, the first portion of the straight line feeds a number of Q−1 SRAM cells located closer to the I/O region 34, and the second portion of the straight line feeds a number of N-Q+1 (defined as P) SRAM cells located further from the I/O region 34. In some embodiments, Q=N−63, meaning the last 64 (P=64) SRAM cells are fed by the narrower portion of a bit line, while rest of the N-64 SRAM cells in the same row are fed by the wider portion of a bit line. In some embodiments, Q=N−31, meaning the last 32 (P=32) SRAM cells are fed by the narrower portion of a bit line, while rest of the N−32 SRAM cells in the same row are fed by the wider portion of a bit line. In some embodiments, P is larger than 0 and not larger than 64 (0<P≤64). This range is not arbitrary and not trivial, as the last 64 SRAM cells may suffer from the parasitic capacitance the most. In furtherance of some embodiments, P is not less than 32 and not larger than 64 (32≤P≤64). In some embodiments, P may equal to a quarter of N (P=N/4), meaning a last quarter of the SRAM cells at the far end in reference to the I/O periphery are fed by a narrower portion of a bit line. In some other embodiments, P may equal to a half of N (P=N/2), meaning a last half of the SRAM cells at the far end in reference to the I/O periphery are fed by a narrower portion of a bit line.

Since the bit line width affects parasitic capacitance which may hinder the circuit speed, the smaller width Wb2 reduces parasitic capacitance, which improves circuit speed and reduces power consumption for the SRAM cells in the last few columns of the memory array 32, without compromising the voltage headroom for the rest of the SRAM cells along the bit lines. Meanwhile, the larger width Wb1 reduces resistance, which increases voltage headroom along the bit lines and improves signal integrity. Even though the larger width Wb1 introduces more parasitic capacitance for the first few columns of the memory array 32, the benefits of having a less voltage drop for all the SRAM cells along the bit lines outweigh the slight circuit speed tradeoffs due to having slightly more parasitic capacitance. In various embodiments, a ratio between the larger width Wb1 and the width W1 of the active region 205A (FIG. 5) in a high-current SRAM cell (i.e., a SRAM cell with W1>W2) ranges between about 1.5 and about 5 (1.5<Wb1/W1≤5), and a ratio between the smaller width Wb2 and the width W1 of the active region 205A in a high-current SRAM cell ranges between about 1 and about 1.5 (1<Wb2/W1≤1.5). These ranges are not trivial or arbitrary. If Wb1/W1 is smaller than about 1.5, there may be not enough voltage headroom for a long bit line; if Wb1/W1 is larger than about 5, the bit line may be too wide and intersect adjacent power/signal lines; if Wb2/W1 is smaller than about 1, the bit line may become too resistive and slow down circuit speed reversely; and if Wb2/W1 is larger than about 1.5, the parasitic capacitance may be too large and the circuit speed may be compromised. Similarly, in various embodiments, a ratio between the larger width Wb1 and the width W1 of the active region 205A (FIG. 5) in a high-density SRAM cell (i.e., a SRAM cell with W1=W2) ranges between about 3 and about 15 (3<Wb1/W1≤15), and a ratio between the smaller width Wb2 and the width W1 of the active region 205A in a high-density SRAM cell ranges between about 2 and about 3 (2<Wb2/W1≤3),

The transition from the larger width Wb1 to the smaller width Wb2 may occur on the cell boundary between Column Q−1 and Column Q. State differently, the transition from the larger width Wb1 to the smaller width Wb2 creates a jog, and the jog may be located at the cell boundary between Column Q−1 and Column Q. Alternatively, the transition of the widths (or the jog) may locate inside the cell boundary of the SRAM cells at the Column Q−1 or the cell boundary of the SRAM cells at the Column Q. FIG. 9 illustrates an enlarged view of a region 350 where a jog locates. Each of the bit lines (BL or BLB) has a first edge facing away from the VDD line (facing the VSS landing pad instead) and a second edge facing the VDD line. The jog has a first distance J1 to the first edge and a second distance J2 to the second edge. In the illustrated embodiment, J1<J2, meaning a centerline of the narrower segment of the bit line is offset away from the VDD line with respect to a centerline of the wider segment of the bit line. In other words, the jog may not be necessarily located at a center of the bit line but shifted away from the VDD line (towards the VSS landing pad instead). Such a structural design is to provide more landing area for the source/drain contact via 270I (or 270J, as shown in FIG. 6) which may be offset from a center line of the bit line. State differently, since the jog and the source/drain contact via 270I/270J may be both located at the cell boundary between Column Q−1 and Column Q and thus overlap, shifting the jog offset from the center line of the bit line may provide larger landing area for the source/drain contact via 270I/270J to mitigate overlaying inaccuracy during manufacturing processes. Alternatively, depending on exact location of the source/drain contact via 270I/270J, the jog may be located at a center of the bit line (J1=J2) or shifted towards the VDD line (J1>J2). With reference to the VDD line sandwiched between the BL and BLB lines, the location of the jog with J1 and J2 distances on the BL line is symmetric to the location of the jog with J1 and J2 distances on the BLB line.

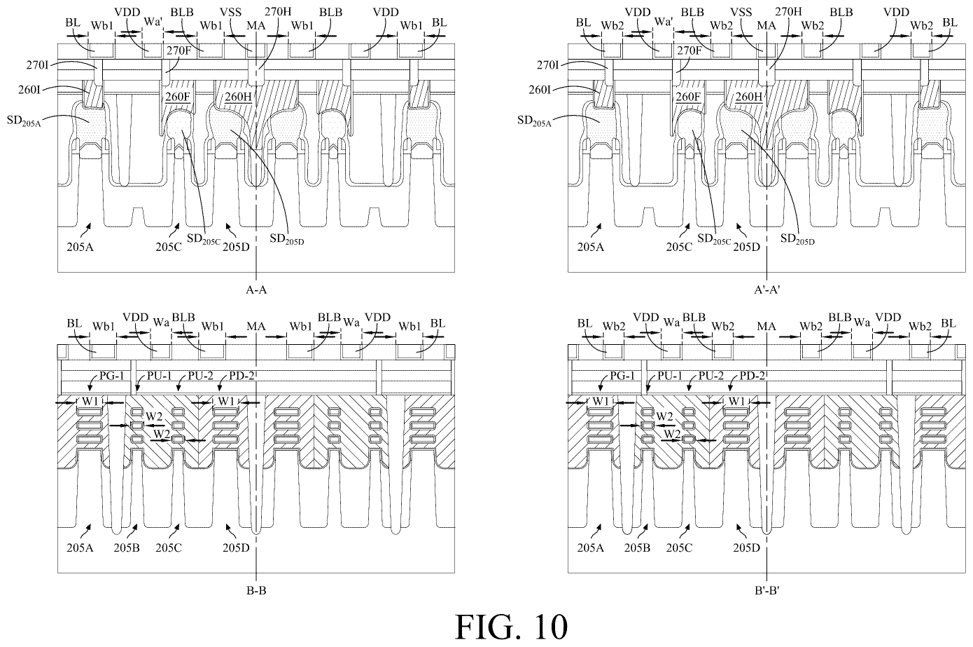

FIG. 10 illustrates fragmentary cross-sectional views along cross sections A-A, B B, A′-A′, and B′-B′ in FIG. 9, respectively. As shown in FIG. 9, the cross-section A-A cuts through source/drain regions along a cell boundary between the memory cells BC₁₁ and BC₁₂ and between the memory cells BC₂₁ and BC₂₂; the cross-section B-B cuts through the gate structures 340 of the memory cells BC₁₁ and BC₂₁; the cross-section A′-A′ cuts through source/drain regions along a cell boundary between the memory cells BC_{1Q-1} and BC_{1Q} and between the memory cells BC_{2Q-1} and BC_{2Q}; and the cross-section B′-B′ cuts through the gate structures 340 of the memory cells BC_{1Q} and BC_{2Q}. In FIG. 10, each cross section is symmetric with respect to a mirror axis MA.

Reference is now made to the cross sections A-A and B-B collectively, which show the wider bit line width Wb1. The active region 205A includes a plurality of nanostructures as channel layers vertically stacked above a fin-shape base. The channel layers provide the channel region for the n-type pass-gate transistor PG-1. Measured on the topmost channel layer, the active region 205A have a width W1. In the source/drain region, a source/drain epitaxial feature SD_{205A} is epitaxially grown on the fin-shape base of the active region 205A. The source/drain epitaxial feature SD_{205A} is electrically coupled to the bit line BL through S/D contact 260I and S/D contact via 270I. The portion of the bit line BL has a first width Wb1, which is larger than a second width Wb2. The active region 205B includes a plurality of nanostructures as channel layers vertically stacked above a fin-shape base. The channel layers provide the channel region for the p-type pull-up transistor PU-1. Measured on the topmost channel layer, the active region 205B have a width W2. In a high-current SRAM cell, the width W2 is smaller than the width W1 (W2<W1); in a high-density SRAM cell, the width W2 may equal the width W1 (W1=W2). The active region 205C includes a plurality of nanostructures as channel layers vertically stacked above a fin-shape base. The channel layers provide the channel region for the p-type pull-up transistor PU-2. Measured on the topmost channel layer, the active region 205C have a width W2. In the source/drain region, a source/drain epitaxial feature SD_{205C} is epitaxially grown on the fin-shape base of the active region 205C. The source/drain epitaxial feature SD_{205C} is electrically coupled to the VDD line through S/D contact 260F and S/D contact via 270F. The cross section A-A may cut along a jog portion of the VDD line, which has a width Wa′ that is larger than a width Wa of the VDD line in the cross section B-B. The width Wb1 of the bit line BL may be wider than both the widths Wa and Wa′ as illustrated; alternatively, the width Wb1 may be larger than the width Wa but smaller than the width Wa′ of the jog portion. The selection of widths may dependent on specific circuit performance needs. The active region 205D includes a plurality of nanostructures as channel layers vertically stacked above a fin-shape base. The channel layers provide the channel region for the n-type pull-down transistor PD-2. Measured on the topmost channel layer, the active region 205D have a width W1. In the source/drain region, a source/drain epitaxial feature SD_{205D} is epitaxially grown on the fin-shape base of the active region 205D. The source/drain epitaxial feature SD_{205D} is electrically coupled to the VSS landing pad through S/D contact 260H and S/D contact via 270H. The mirror image placement of the SRAM cells allows a larger S/D contact 260H lands on the source/drain epitaxial feature SD_{205D}. Cross sections A-A and B-B also depicts bit line bar BLB disposed between the VDD line and the VSS landing pad. The portion of the bit line bar BLB has the same width Wb1 as the portion of the bit line BL.

Reference is now made to the cross sections A′-A′ and B′-B′ collectively, which show the narrower bit line width Wb2. The active region 205A includes a plurality of nanostructures as channel layers vertically stacked above a fin-shape base. The channel layers provide the channel region for the n-type pass-gate transistor PG-1. Measured on the topmost channel layer, the active region 205A have a width W1. In the source/drain region, a source/drain epitaxial feature SD_{205A} is epitaxially grown on the fin-shape base of the active region 205A. The source/drain epitaxial feature SD_{205A} is electrically coupled to the bit line BL through S/D contact 260I and S/D contact via 270I. The portion of the bit line BL has a second width Wb2, which is smaller than the first width Wb1. The active region 205B includes a plurality of nanostructures as channel layers vertically stacked above a fin-shape base. The channel layers provide the channel region for the p-type pull-up transistor PU-1. Measured on the topmost channel layer, the active region 205B have a width W2. In a high-current SRAM cell, the width W2 is smaller than the width W1 (W2<W1); in a high-density SRAM cell, the width W2 may equal the width W1 (W1=W2). The active region 205C includes a plurality of nanostructures as channel layers vertically stacked above a fin-shape base. The channel layers provide the channel region for the p-type pull-up transistor PU-2. Measured on the topmost channel layer, the active region 205C have a width W2. In the source/drain region, a source/drain epitaxial feature SD_{205C} is epitaxially grown on the fin-shape base of the active region 205C. The source/drain epitaxial feature SD_{205C} is electrically coupled to the VDD line through S/D contact 260F and S/D contact via 270F. The cross section A′-A′ may cut along a jog portion of the VDD line, which has a width Wa′ that is larger than a width Wa of the VDD line in the cross section B′-B′. The width Wb2 of the bit line BL may be wider than both the widths Wa and Wa′ as illustrated; alternatively, the width Wb2 may be larger than the width Wa but smaller than the width Wa′ of the jog portion. The selection of widths may dependent on specific circuit performance needs. The active region 205D includes a plurality of nanostructures as channel layers vertically stacked above a fin-shape base. The channel layers provide the channel region for the n-type pull-down transistor PD-2. Measured on the topmost channel layer, the active region 205D have a width W1. In the source/drain region, a source/drain epitaxial feature SD_{205D} is epitaxially grown on the fin-shape base of the active region 205D. The source/drain epitaxial feature SD_{205D}) is electrically coupled to the VSS landing pad through S/D contact 260H and S/D contact via 270H. The mirror image placement of the SRAM cells allows a larger S/D contact 260H lands on the source/drain epitaxial feature SD_{205D}. Cross sections A′-A′ and B′-B′ also depicts bit line bar BLB disposed between the VDD line and the VSS landing pad. The portion of the bit line bar BLB has the same width Wb2 as the portion of the bit line BL.

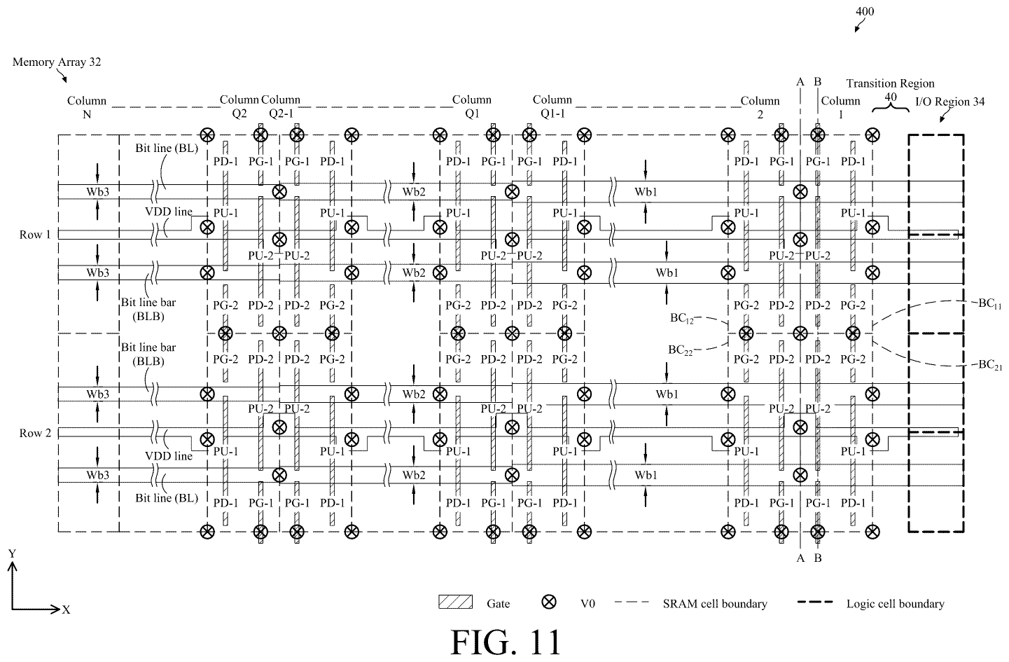

In furtherance of some embodiments, the semiconductor memory design may optionally provide a third bit line width Wb3 that is even smaller than Wb2 (Wb3<Wb2<Wb1). FIG. 11 illustrates such an embodiment. Particularly, FIG. 11 illustrates the V0 level and M0 level of a layout 400 of the portion of the memory macro 30 (FIG. 2), in which each of the bit lines (BL or BLB) includes a first portion (or segment) with a larger width Wb1 for SRAM cells at the near end in reference to the I/O periphery, a second portion (or segment) with a medium width Wb2 for SRAM cells in the middle of the memory array, and a third portion (or segment) with a narrower width Wb3 for SRAM cells at the far end in reference to the I/O periphery. The width transition (first jog) from Wb1 to Wb2 may occur at a cell boundary between the SRAM cells at Column Q1−1 and Column Q1, and the width transition (second jog) from Wb2 to Wb3 may occur at a cell boundary between the SRAM cells at Column Q2−1 and Column Q2. In one example, the memory array has a total of N columns grouped in 8 banks with each bank having a number of N/8 columns of SRAM cells; in the same row, the last bank (the last N/8 columns) of SRAM cells are fed by the third portion of the bit line with the narrower width Wb3, the first five banks (the first 5N/8 columns) of SRAM cells are fed by the first portion of the bit line with the larger width Wb1, and the rest 2 banks (the middle N/4 columns) are fed by the second portion of the bit line with the medium width Wb2. Taking N=256 as an example, each bank has 32 columns of SRAM cells, the last bank (32 columns) of SRAM cells are coupled to the third portion of the bit line with the width Wb3, the first to fifth banks (160 columns) of SRAM cells are coupled to the first portion of the bit line with the width Wb1, and the sixth to seventh banks (64 columns) of SRAM cells are coupled to the second portion of the bit line with the width Wb2.

If the third bit line width Wb3 is provided in the semiconductor memory design, a ratio between the smallest width Wb3 and the width W1 of the active region 205A (FIG. 5) in a high-current SRAM cell ranges between about 0.3 and about 1 (0.3<Wb3/W1≤1) in some embodiments. Again, these ranges are not trivial or arbitrary. If Wb3/W1 is smaller than about 0.3, the bit line may become too resistive and slow down circuit speed of a micro cache reversely; and if Wb3/W1 is larger than about 1, the parasitic capacitance may be too large and hinder circuit speed of a micro cache. Similarly, a ratio between the smallest width Wb3 (if presented) and the width W1 of the active region 205A in a high-density SRAM cell ranges between about 0.5 and about 2 (0.5<Wb3/W1≤2).

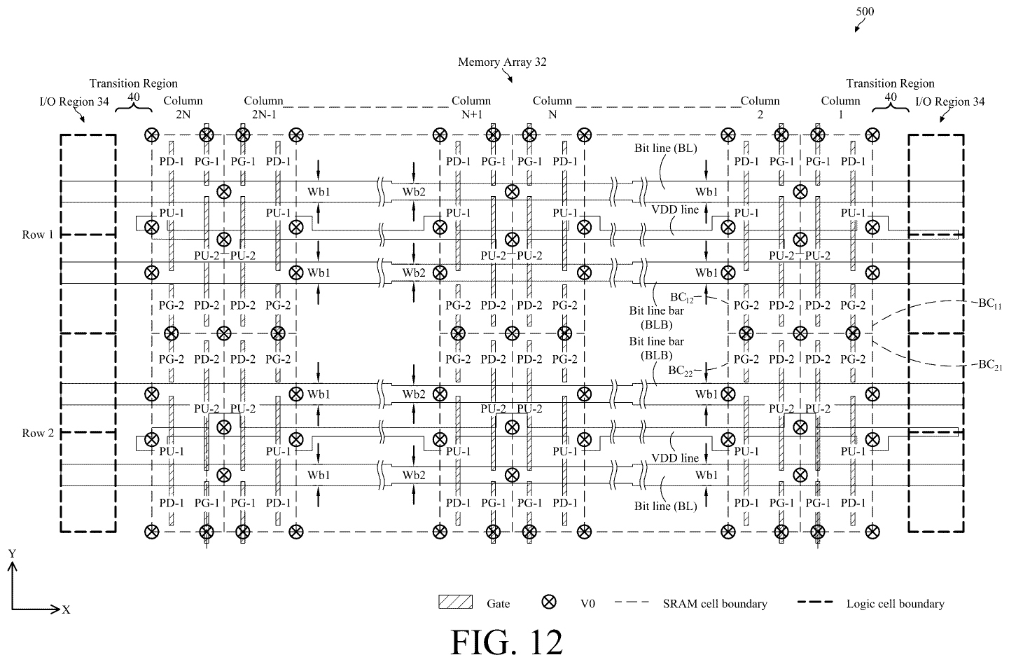

In furtherance of some embodiments, the semiconductor memory design may optionally provide a second I/O region coupled to the memory array from far end in reference to the first I/O region. Each of the bit lines (BL or BLB) extends continuously through the memory array and into the first and second I/O regions from both ends. FIG. 12 illustrates such an embodiment. Particularly, FIG. 12 illustrates the V0 level and M0 level of a layout 500 of the portion of the memory macro 30 (FIG. 2), which includes first two rows (Rows 1-2) of the memory array 32 and a portion of the logic cells in the first and second I/O regions 34. The first and second I/O regions sandwich the memory array 32. The memory array 32 has 2N columns. For simplicity, only the first two rows (Rows 1-2) of the memory array 32 are illustrated in FIG. 12. In the same row, each of the bit lines (BL or BLB) has two end portions having the larger width Wb1 and a middle portion having the smaller width Wb2. State differently, the memory array 32 of 2N columns can be considered of having a first array of N columns with the bit lines with two different widths as arranged in the fashion as discussed with reference to the embodiment of FIG. 9, and a second array of N columns with the bit lines as a mirrored image of the first array with respect to the cell boundary between Column N and Column N+1. Similarly, the memory array 32 of 2N columns can be considered of having a first array of N columns with the bit lines with three different widths as arranged in the fashion as discussed with reference to the embodiment of FIG. 11, and a second array of N columns with the bit lines as a mirrored image of the first array with respect to the cell boundary between Column N and Column N+1.

Various embodiments of the present disclosure illustrate a bit line with a non-uniform width (e.g., different widths along a bit line) in an SRAM array. In one embodiment, an SRAM array may feature two or more bit line widths for memory cells at different distances from I/O periphery, enhancing circuit performance. Different embodiments may have different advantages, and no particular advantage is required of any embodiment.

In one example aspect, the present disclosure provides a semiconductor device. The semiconductor device includes a memory array comprising a plurality of memory cells arranged in a row, and an interconnect structure disposed over the memory cells and comprising a bit line. The bit line is coupled to each of the memory cells arranged in the row. The bit line has a first segment coupled to a first portion of the memory cells and a second segment coupled to a second portion of the memory cells, and the first segment has a first width and the second segment has a second width that is smaller than the first width. In some embodiments, a number of the second portion of the memory cells is less than a number of the first portion of the memory cells. In some embodiments, the number of the second portion of the memory cells is not larger than 64. In some embodiments, the number of the second portion of the memory cells is not less than 32. In some embodiments, the number of the second portion of the memory cells is one fourth of a number of the memory cells arranged in the row. In some embodiments, the bit line as a third segment coupled to a third portion of the memory cells, and the third segment has a third width that is smaller than the second width. In some embodiments, a number of the third portion of the memory cells is less than a number of the second portion of the memory cells, and the number of the second portion of the memory cells is less than a number of the first portion of the memory cells. In some embodiments, the semiconductor device further includes a logic circuit disposed by the memory array and coupled to the memory cells arranged in the row. The first portion of the memory cells are located closer to the logic circuit than the second portion of the memory cells. In some embodiments, the logic circuit is a first logic circuit, and the semiconductor device further includes a second logic circuit disposed by the memory array and coupled to the memory cells arranged in the row. The first logic circuit and the second logic circuit sandwich the memory array along a lengthwise direction of the row. The bit line has a third segment coupled to a third portion of the memory cells. The third portion of the memory cells are located closer to the second logic circuit than the first portion of the memory cells. The third segment has a third width that is equal to the first width. In some embodiments, the interconnect structure further comprises a complimentary bit line coupled to each of the memory cells arranged in the row. The complimentary bit line has a first segment coupled to the first portion of the memory cells and a second segment coupled to the second portion of the memory cells. The first segment of the complimentary bit line is narrower than the second segment of the complimentary bit line.

Another aspect of the present disclosure provides a semiconductor device. The semiconductor device includes a plurality of memory cells arranged along a first direction, each of the memory cells including at least a pass-gate transistor formed on an n-type active region and a pull-up transistor formed on a p-type active region, a voltage line suspended above the memory cells and extending lengthwise along the first direction, the voltage line being coupled to the pull-up transistors of the memory cells, and a signal line suspended above the memory cells and extending lengthwise along the first direction. The signal line includes a first segment coupled to the pass-gate transistors of a first portion of the memory cells and a second segment coupled to the pass-gate transistors of a second portion of the memory cells. The first segment has a first width and the second segment has a second width that is smaller than the first width. In some embodiments, the signal line is a bit line. In some embodiments, the n-type active region has a third width and the p-type active region has a fourth width that is smaller than the third width. In some embodiments, a ratio of the first width over the third width ranges between about 1.5 and about 5, and a ratio of the second width over the third width ranges between about 1 and about 1.5. In some embodiments, the n-type active region has a third width and the p-type active region has a fourth width that is equal to the third width. In some embodiments, a ratio of the first width over the third width ranges between about 3 and about 15, and a ratio of the second width over the third width ranges between about 2 and about 3. In some embodiments, a centerline of the second segment is shifted away from the voltage line with respect to a centerline of the first segment.

Yet another aspect of the present disclosure provides a semiconductor device. The semiconductor device includes a memory array including memory cells arranged in M rows and N columns, M and N each being an integer, a logic region adjacent the memory array and coupled to the memory cells, and an interconnect structure disposed over the memory array and the logic region. The interconnect structure includes a signal line suspended directly above one of the M rows of the memory cells. The signal line includes a first segment coupled to the memory cells in a first column to a (Q−1)^{th} column of the one of the M rows and a second segment coupled to the memory cells in a Q^{th} column to a Nth column of the one of the M rows, Q is an integer larger than 1 and smaller than N, the first column is located closer to the logic region than the Nth column, and the first segment has a first width and the second segment has a second width that is smaller than the first width. In some embodiments, N is larger than 128 and N−Q+1 is not larger than 64. In some embodiments, N−Q+1 is one fourth of N.

The foregoing has outlined features of several embodiments. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A semiconductor device, comprising:
a cell array comprising a plurality of circuit cells arranged in a row; and
an interconnect structure disposed over the cell array, the interconnect structure comprising a plurality of interconnect layers, each of the interconnect layers comprising metal lines disposed in a dielectric layer,
wherein one of the metal lines is a signal line extending straight in a direction of the row and coupled to each of the circuit cells arranged in the row through contacts, wherein the signal line has a first segment coupled to a first plurality of the circuit cells located in a first portion of the row and a second segment coupled to a second plurality of the circuit cells located in a second portion of the row, and wherein the first segment has a first width and the second segment has a second width that is smaller than the first width.

2. The semiconductor device of claim 1, wherein the signal line is located in a bottommost one of the interconnect layers of the interconnect structure.

3. The semiconductor device of claim 1, wherein the cell array is a memory cell array, the circuit cells are memory cells, and the signal line is a bit line.

4. The semiconductor device of claim 3, wherein the circuit cells are static random access memory (SRAM) cells.

5. The semiconductor device of claim 1, wherein a number of the second plurality of the circuit cells is less than a number of the first plurality of the circuit cells.

6. The semiconductor device of claim 5, wherein the number of the second plurality of the circuit cells is between 32 and 64.

7. The semiconductor device of claim 5, wherein the number of the second plurality of the circuit cells is one fourth of a total number of the circuit cells in the row.

8. The semiconductor device of claim 1, wherein the signal line has a third segment coupled to a third plurality of the circuit cells located in a third portion of the row, the second portion is disposed between the first and third portions, and wherein the third segment has a third width smaller than the second width.

9. The semiconductor device of claim 8, wherein a number of the third plurality of the circuit cells is less than a number of the second plurality of the circuit cells, and wherein the number of the second plurality of the circuit cells is less than a number of the first plurality of the circuit cells.

10. The semiconductor device of claim 1, further comprising:
a logic circuit adjacent to the cell array and coupled to the circuit cells arranged in the row, wherein the signal line extends to a potion above the logic circuit, and wherein the first portion of the row is located between the logic circuit and the second portion of the row.

11. A semiconductor device, comprising:
a plurality of circuit cells arranged in a row, an n-type active region and a p-type active region extending through the circuit cells arranged in the row, each of the circuit cells including at least a pass-gate transistor formed on the n-type active region and a pull-up transistor formed on the p-type active region;
a voltage line suspended above the circuit cells and extending lengthwise along a longitudinal direction of the row, the voltage line coupled to the pull-up transistors of the circuit cells in the row; and
a signal line suspended above the circuit cells and extending lengthwise along the longitudinal direction of the row, the signal line including a first segment coupled to the pass-gate transistors of a first portion of the circuit cells and a second segment coupled to the pass-gate transistors of a second portion of the circuit cells, the second segment abutting the first segment, the first segment having a first width, and the second segment having a second width smaller than the first width.

12. The semiconductor device of claim 11, wherein the signal line is a bit line.

13. The semiconductor device of claim 11, wherein a centerline of the second segment is aligned with a centerline of the first segment.

14. The semiconductor device of claim 11, wherein a centerline of the second segment is offset from a centerline of the first segment in a direction perpendicular to the longitudinal direction of the row.

15. The semiconductor device of claim 11, further comprising:
an input/output (I/O) region disposed adjacent to the row, wherein the first segment is disposed between the I/O region and the second segment, and the signal line extends continuously into the I/O region.

16. The semiconductor device of claim 15, wherein the voltage line extends continuously into the I/O region.

17. The semiconductor device of claim 11, wherein the n-type active region has a third width and the p-type active region has a fourth width smaller than the third width, a ratio of the first width over the third width ranges between about 1.5 and about 5, and a ratio of the second width over the third width ranges between about 1 and about 1.5.

18. A semiconductor device, comprising:
a cell array including circuit cells arranged in M rows and N columns, M and N each being an integer;
an input/output (I/O) region adjacent the cell array and coupled to the circuit cells; and
an interconnect structure disposed over the cell array and the I/O region, wherein the interconnect structure includes a signal line suspended above one of the M rows of the circuit cells, and
wherein:
the signal line includes a first segment coupled to the circuit cells in a first column to a (Q−1)^{th} column of the one of the M rows and a second segment coupled to the circuit cells in a Q^{th} column to a N^{th} column of the one of the M rows,
Q is an integer larger than 1 and smaller than N,
the first column is located closer to the I/O region than the N^{th} column, and
the first segment has a first width and the second segment has a second width smaller than the first width.

19. The semiconductor device of claim 18, wherein N is larger than 128 and N−Q+1 is not larger than 64.

20. The semiconductor device of claim 18, wherein N−Q+1 is one fourth of N.
